(19) United States
(12) Patent Application Publication
(10) Pub. No.: US 2026/0036905 A1
(43) Pub. Date: Feb. 5, 2026

(54) RESIST UNDERLAYER COMPOSITION, AND METHOD OF FORMING PATTERNS USING THE COMPOSITION

(71) Applicant: SAMSUNG SDI CO., LTD., Yongin-si (KR)

(72) Inventors: Jihye LEE, Suwon-si (KR); Seongjin KIM, Suwon-si (KR); Jaemin LEE, Suwon-si (KR); Sungwoo JUNG, Suwon-si (KR); Jungin MUN, Suwon-si (KR)

(21) Appl. No.: 19/282,690

(22) Filed: Jul. 28, 2025

(30) Foreign Application Priority Data
Aug. 1, 2024 (KR) 10-2024-0102730

(51) Int. Cl. G03F 7/038; C09D 125/18; G03F 7/095; G03F 7/16

(52) U.S. Cl. CPC G03F 7/0388; C09D 125/18; G03F 7/0382; G03F 7/095; G03F 7/168

(57) ABSTRACT

A resist underlayer composition, and a method of forming a pattern using the resist underlayer composition are disclosed. The resist underlayer composition including a polymer including a structural unit represented by Chemical Formula 1 and a structural unit represented by Chemical Formula 2, wherein the structural unit represented by Chemical Formula 1 and the structural unit represented by Chemical Formula 2 are included in a molar ratio of about 13:1 to about 1:1, and a solvent.

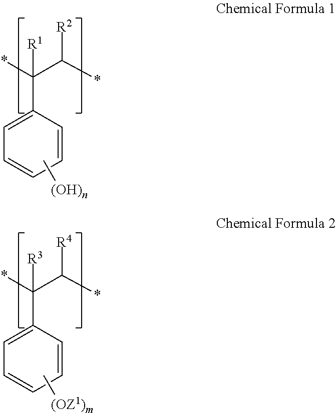

### CROSS-REFERENCE TO RELATED APPLICATION

The present application claims priority to and the benefit of Korean Patent Application No. 10-2024-0102730, filed on Aug. 1, 2024, in the Korean Intellectual Property Office, the entire content of which is incorporated herein by reference.

### BACKGROUND

### 1. Field

This disclosure relates to a resist underlayer composition and a method of forming a pattern using the same.

### 2. Description of the Related Art

Recently, the semiconductor industry has ultra-fine techniques capable of producing patterns of several to several tens of nanometers in size. Such ultrafine techniques depend on effective lithographic techniques.

A lithographic technique is a processing method that includes coating a photoresist film on a semiconductor substrate, such as a silicon wafer. to form a thin film, irradiating the photoresist film with activating radiation, such as ultraviolet rays, through a mask pattern on which the device pattern is formed, developing the resultant to obtain a photoresist pattern, and etching the substrate using the photoresist pattern as a protective layer to form a fine pattern corresponding to the device pattern on the surface of the substrate.

As semiconductor patterns become increasingly finer (e.g., smaller), the thickness of the photoresist layer is desired or required to be thin, and accordingly, the thickness of the resist underlayer is also desired or required to be thin. The resist underlayer should not collapse the photoresist pattern even if it is thin, should have good or suitable adhesion to the photoresist, and should be formed with a substantially uniform thickness. In addition, the resist underlayer is desired or required to have a high refractive index and low extinction coefficient for the light used in photolithography and a faster etch rate than the photoresist layer.

### SUMMARY

An aspect according to embodiments of the present disclosure is directed toward a resist underlayer composition that provides a resist underlayer in which pattern collapse of the resist does not occur or is reduced even in a fine patterning process, and has improved sensitivity to an exposure light source, thereby improving patterning performance and energy efficiency.

An aspect according to embodiments of the present disclosure is directed toward a method of forming a pattern using the resist underlayer composition.

Additional aspects will be set forth in part in the description which follows and, in part, will be apparent from the description, or may be learned by practice of the presented embodiments of the disclosure.

A resist underlayer composition according to some example embodiments includes a polymer including a structural unit represented by Chemical Formula 1 and a structural unit represented by Chemical Formula 2, and a solvent, wherein in the polymer, a molar ratio between the structural unit represented by Chemical Formula 1 and the structural unit represented by Chemical Formula 2 is about 13:1 to about 1:1:

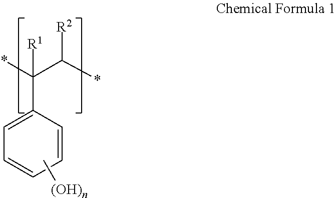

In Chemical Formula 1,
R¹ and R² may each independently be hydrogen, deuterium, or a substituted or unsubstituted C1 to C5 alkyl group, and
n may be 1 or 2, and * may be a linking point;

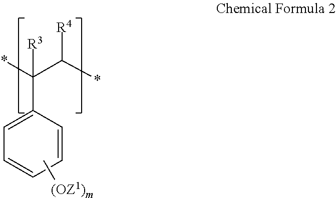

wherein, in Chemical Formula 2,
Z¹ may be a substituted or unsubstituted C1 to C20 alkyl group; a substituted or unsubstituted C3 to C20 cycloalkyl group; a substituted or unsubstituted C1 to C20 heteroalkyl group; a substituted or unsubstituted C2 to C20 heterocycloalkyl group; —(C═O)OR^{a} (wherein, R^{a} may be hydrogen, deuterium, a substituted or unsubstituted C1 to C10 alkyl group, a substituted or unsubstituted C3 to C20 cycloalkyl group, or a substituted or unsubstituted C6 to C20 aryl group); —S(═O)₂R^{b} (wherein, R^{b} may be a halogen atom, a substituted or unsubstituted C1 to C20 alkyl group, a substituted or unsubstituted C1 to C20 alkoxy group, a substituted or unsubstituted C6 to C20 aryloxy group, or a substituted or unsubstituted C6 to C20 aryl group); —SiR^{c}R^{d}R^{e} (wherein, R^{C} to R^{e} may each independently be a substituted or unsubstituted C1 to C10 alkyl group, or a substituted or unsubstituted C1 to C10 alkoxy group); and/or a (e.g., any suitable) combination thereof,
R³ and R⁴ may each independently be hydrogen, deuterium, or a substituted or unsubstituted C1 to C5 alkyl group,
m may be one of integers of 1 to 3, and
* may be a linking point.

Z¹ in Chemical Formula 2 may be —(C═O)OR^{a} (wherein, R^{a} is hydrogen, deuterium, a substituted or unsubstituted C1 to C10 alkyl group, a substituted or unsubstituted C3 to C20 cycloalkyl group, or a substituted or unsubstituted C6 to C20 aryl group).

In Chemical Formula 2, m may be 1.

The structural unit represented by Chemical Formula 1 may be represented by Chemical Formula 1-1 or Chemical Formula 1-2:

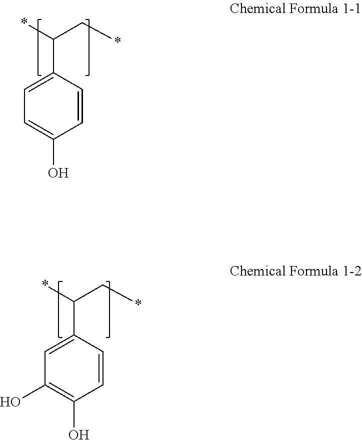

The structural unit represented by Chemical Formula 2 may be represented by Chemical Formula 2-1:

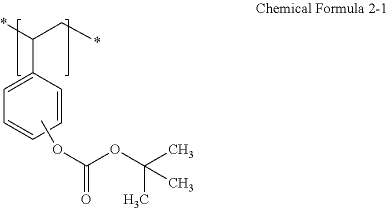

In the polymer, the molar ration between the structural unit represented by Chemical Formula 1 and the structural unit represented by Chemical Formula 2 may be about 6:1 to about 1:1.

A weight average molecular weight of the polymer may be from about 1,000 g/mol to about 100,000 g/mol.

The polymer may be about 0.1 wt % to about 2 wt % in amount based on a total weight of the resist underlayer composition.

The composition may further include one or more polymers selected from among an acrylic resin, an epoxy resin, a novolac-based resin, a glycoluril-based resin, and a melamine-based resin.

The composition may further include an additive selected from among a surfactant, a thermal acid generator, a photoacid generator, a plasticizer, and/or a (e.g., any suitable) combination thereof.

According to some example embodiments, a method of forming a pattern includes forming an etching target layer on a substrate, forming a resist underlayer by applying the resist underlayer composition according to some example embodiments, forming a photoresist pattern on the resist underlayer, and sequentially etching the resist underlayer and the etching target layer using the photoresist pattern as an etching mask.

The resist underlayer composition according to some example embodiments can provide a resist underlayer in which pattern collapse of the resist does not occur even in a fine patterning process, and has improved sensitivity to an exposure light source, thereby enabling improved patterning performance and energy efficiency.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIGS. 1a-1f are cross-sectional views illustrating a method of forming a pattern using a resist underlayer composition according to some example embodiments.

### DETAILED DESCRIPTION

Example embodiments of the present disclosure will hereinafter be described in more detail, and may be easily practiced by a person skilled in the art. However, this disclosure may be embodied in many different forms and is not construed as limited to the example embodiments set forth herein.

In the drawings, the thickness of layers, films, panels, regions, and/or the like, are exaggerated for clarity and like reference numerals designate like elements throughout, and duplicative descriptions thereof may not be provided in the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

As used herein, if (e.g., when) a definition is not otherwise provided, the term “substituted” refers to replacement of a hydrogen atom of a compound or moiety by a substituent selected from among deuterium, a halogen (F, Br, C1, or I), a hydroxyl group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and/or a (e.g., any suitable) combination thereof.

In addition, two adjacent substituents from among the halogen atom (F, Br, Cl, or I), hydroxyl group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, the term “heterocyclic group” includes a heteroaryl group and a cyclic group including at least one heteroatom selected from among N, O, S, P, and Si instead of carbon (C) as a ring forming atom, derived from a cyclic compound such as an aryl group, a cycloalkyl group, a fused ring thereof, and/or a (e.g., any suitable) combination thereof. When the heterocyclic group is a fused ring, each or the entire ring of the heterocyclic group may include at least one heteroatom.

For example, a substituted or unsubstituted aryl group and/or a substituted or unsubstituted heterocyclic group may include (e.g., may be) a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiophenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups (e.g., a fused ring with two or more of the foregoing groups combined together), but the present disclosure is not limited thereto.

As used herein, if (e.g., when) specific definition is not otherwise provided, the term “combination” refers to mixing or copolymerization.

Additionally, as used herein, the term “polymer” may include both (e.g., simultaneously) oligomers and polymers.

Unless otherwise specified in the present specification, the weight average molecular weight is measured by dissolving a powder sample in tetrahydrofuran (THF) and then obtaining the weight average molecular weight using 1200 series Gel Permeation Chromatography (GPC) of Agilent Technologies (column is Shodex Company LF-804, standard sample is Shodex company polystyrene).

In addition, unless otherwise defined in the specification, “*” indicates a linking point of a structural unit or a moiety of a polymer.

In the semiconductor industry, there is a constant demand to reduce the size of chips. In order to meet this trend, a line width of the resist patterned in lithography technology is desired to or should be reduced to a level of several tens of nanometers, and the pattern formed in this way is used to transfer the pattern to a lower material (e.g., a material located beneath the resist) by using an etching process on a lower substrate. However, as the pattern size of the resist becomes smaller, a height (aspect ratio) of the resist that can withstand the line width is limited, and accordingly, the resists may not have sufficient resistance in the etching step (e.g., act or task). Therefore, a resist underlayer has been used to compensate for this if (e.g., when) a thin resist material is used, if (e.g., when) the substrate to be etched is thick, and/or if (e.g., when) a deep pattern is desired or required.

The resist underlayer is desired or required to become thinner as the thickness of the resist becomes thinner, and the photoresist pattern is desired to or should not collapse even if the resist underlayer is thin. For this purpose, the resist underlayer is desired to or should have excellent or suitable adhesion to the photoresist. In addition, in forming a thin resist underlayer, coating uniformity of the resist underlayer composition and flatness of the resist underlayer produced therefrom is desired to or should be improved, and sensitivity to the exposure light source is desired to or should be improved to improve pattern formability and energy efficiency.

A resist underlayer composition according to some example embodiments includes a polymer including a structural unit represented by Chemical Formula 1 and a structural unit represented by Chemical Formula 2, and a solvent, wherein in the polymer, the structural unit represented by Chemical Formula 1 and the structural unit represented by Chemical Formula 2 are included in a molar ratio of about 13:1 to about 1:1:

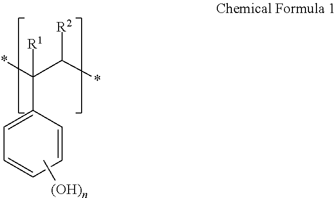

In Chemical Formula 1,
R¹ and R² may each independently be hydrogen, deuterium, or a substituted or unsubstituted C1 to C5 alkyl group,
n may be 1 or 2, and * may be a linking point (e.g., to an adjacent structural unit);

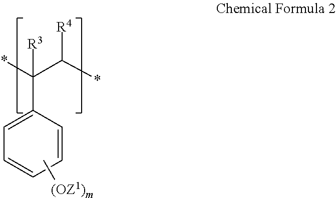

In Chemical Formula 2,
Z¹ may be a substituted or unsubstituted C1 to C20 alkyl group, a substituted or unsubstituted C3 to C20 cycloalkyl group, a substituted or unsubstituted C1 to C20 heteroalkyl group, a substituted or unsubstituted C2 to C20 heterocycloalkyl group, —(C═O)OR^{a} (wherein, R^{a} may be hydrogen, deuterium, a substituted or unsubstituted C1 to C10 alkyl group, a substituted or unsubstituted C3 to C20 cycloalkyl group, or a substituted or unsubstituted C6 to C20 aryl group), —S(═O)₂R^{b} (wherein, R^{b} may be a halogen atom, a substituted or unsubstituted C1 to C20 alkyl group, a substituted or unsubstituted C1 to C20 alkoxy group, a substituted or unsubstituted C6 to C20 aryloxy group, or a substituted or unsubstituted C6 to C20 aryl group), —SiR^{c}R^{d}R^{e} (wherein, R^{c} to R^{e} may each independently be a substituted or unsubstituted C1 to C10 alkyl group, or a substituted or unsubstituted C1 to C10 alkoxy group), and/or a (e.g., any suitable) combination thereof,
R³ and R⁴ may each independently be hydrogen, deuterium, or a substituted or unsubstituted C1 to C5 alkyl group,
m may be one of integers of 1 to 3, and
* may be a linking point.

Z¹ in the substituent —(OZ¹) of the structural unit represented by Chemical Formula 2 in the polymer of the composition according to some example embodiments, may be cleaved by an acid upon exposure. As a result, the content (e.g., amount) of hydroxyl groups in the polymer can increase as the —(OZ¹) is converted to a hydroxyl group during the baking (e.g., heating, curing, or annealing) process of the resist underlayer. Accordingly, the adhesion between the photoresist and the resist underlayer formed from the composition can be improved, and pattern collapse can be suppressed or reduced.

In addition, the resist underlayer composition according to some example embodiments of the present disclosure includes the structural unit represented by Chemical Formula 1 and the structural unit represented by Chemical Formula 2 in a molar ratio of about 13:1 to about 1:1, so that a resist underlayer manufactured from the composition has increased adhesion to a photoresist, thereby suppressing or reducing collapse of a pattern.

In some embodiments, in Chemical Formula 2, Z¹ may be, for example, a substituted or unsubstituted C1 to C20 alkyl group, a substituted or unsubstituted C3 to C20 cycloalkyl group, a substituted or unsubstituted C1 to C20 heteroalkyl group, a substituted or unsubstituted C2 to C20 heterocycloalkyl group, —(C═O)OR^{a} (wherein, R^{a} may be hydrogen, deuterium, a substituted or unsubstituted C1 to C10 alkyl group, a substituted or unsubstituted C3 to C20 cycloalkyl group, or a substituted or unsubstituted C6 to C20 aryl group), —S(═O)₂R^{b} (wherein, R^{b} may be a halogen atom, a substituted or unsubstituted C1 to C20 alkyl group, a substituted or unsubstituted C1 to C20 alkoxy group, a substituted or unsubstituted C6 to C20 aryloxy group, or a substituted or unsubstituted C6 to C20 aryl group), and/or a (e.g., any suitable) combination thereof. In some embodiments, Z¹ may be a substituted or unsubstituted C1 to C20 alkyl group, a substituted or unsubstituted C3 to C20 cycloalkyl group, a substituted or unsubstituted C1 to C20 heteroalkyl group, a substituted or unsubstituted C2 to C20 heterocycloalkyl group, —(C═O)OR^{a} (wherein, R^{a} may be hydrogen, deuterium, a substituted or unsubstituted C1 to C10 alkyl group, a substituted or unsubstituted C3 to C20 cycloalkyl group, or a substituted or unsubstituted C6 to C20 aryl group), and/or a (e.g., any suitable) combination thereof. In some embodiments, Z¹ may be —(C═O)OR^{a} (wherein, the R^{a} may be hydrogen, deuterium, a substituted or unsubstituted C1 to C10 alkyl group, a substituted or unsubstituted C3 to C20 cycloalkyl group, or a substituted or unsubstituted C6 to C20 aryl group), but the present disclosure is not limited thereto. In some embodiments, Z¹ is —(C═O)OR^{a} and R^{a} is a substituted or unsubstituted C1 to C10 alkyl group, but the present disclosure is not limited thereto.

In Chemical Formula 1 and in Chemical Formula 2, R¹ to R⁴ may each independently be hydrogen, deuterium, or a substituted or unsubstituted C1 to C5 alkyl group. In some embodiments, R¹ to R⁴ may each independently be hydrogen, but the present disclosure is not limited thereto.

In some embodiments, the structural unit represented by Chemical Formula 1 may be represented by Chemical Formula 1-1 or Chemical Formula 1-2:

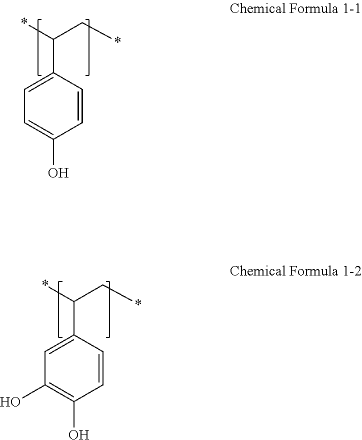

In some embodiments, the structural unit represented by Chemical Formula 2 may be represented by Chemical Formula 2-1:

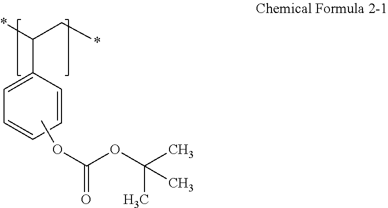

In some example embodiments, the polymer includes the structural unit represented by Chemical Formula 1 and the structural unit represented by Chemical Formula 2 in a molar ratio of about 12:1 to about 1:1, about 11:1 to about 1:1, about 10:1 to about 1:1, about 9:1 to about 1:1, about 8:1 to about 1:1, about 7:1 to about 1:1, about 6:1 to about 1:1, or about 5:1 to about 1:1, but the present disclosure is not limited thereto.

The polymer may have a weight average molecular weight of about 1,000 g/mol to about 100,000 g/mol, for example 3,000 g/mol to 100,000 g/mol, 3,000 g/mol to 90,000 g/mol, 3,000 g/mol to 70,000 g/mol, 3,000 g/mol to 50,000 g/mol, 5,000 g/mol to 50,000 g/mol, or 5,000 g/mol to 30,000 g/mol, but the present disclosure is not limited thereto. By having a weight average molecular weight within the above ranges, a carbon content (e.g., amount) and solubility in the solvent of the resist underlayer composition including the polymer may be suitably adjusted and improved or optimized.

The polymer may be included in an amount of about 0.1 wt % to about 2 wt % based on a total weight (100 wt %) of the resist underlayer composition. In some embodiments, the polymer may be included in an amount of about 0.1 wt % to about 1.5 wt %, for example, about 0.1 wt % to about 1.0 wt %, or about 0.1 wt % to about 0.5 wt % based on a total weight of the resist underlayer composition, but the present disclosure is not limited thereto. By including the polymer within the above ranges in the composition, the thickness, the surface roughness, and a degree of planarization of the resist underlayer may be suitably adjusted.

The resist underlayer composition according to some example embodiments may include a solvent. The solvent is not particularly limited as long as it has sufficient solubility and/or dispersibility for the polymer and compound according to some example embodiments, but may be, for example, propylene glycol, propylene glycol diacetate, methoxypropanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethyl formamide, N,N-dimethyl acetamide, methylpyrrolidone, methyl 2-hydroxyisobutyrate, acetylacetone, ethyl 3-ethoxypropionate, and/or a (e.g., any suitable) combination thereof, but the present disclosure is not limited thereto.

The resist underlayer composition according to some example embodiments may further include one or more polymers selected from among an acrylic resin, an epoxy resin, a novolac-based resin, a glycoluril-based resin, and a melamine-based resin, in addition to the polymer and solvent, but the present disclosure is not limited thereto.

The resist underlayer composition according to some example embodiments may further include an additive including a surfactant, a thermal acid generator, a plasticizer, and/or a (e.g., any suitable) combination thereof.

The surfactant may be used to improve (e.g., reduce) coating defects caused by an increase in a solid content (e.g., amount) if (e.g., when) forming the resist underlayer, and may be, for example, an alkylbenzenesulfonate salt, an alkylpyridinium salt, polyethylene glycol, a quaternary ammonium salt, and/or the like, but the present disclosure is not limited thereto.

The thermal acid generator may be an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, or/and benzoin tosylate, 2-nitrobenzyltosylate, and other organic sulfonic acid alkyl ester may be used, but the present disclosure is not limited thereto.

The plasticizer is not particularly limited, and a variety of suitable plasticizers may be used. Examples of a plasticizer may include low molecular weight compounds such as phthalic acid esters, adipic acid esters, phosphoric acid esters, trimellitic acid esters, citric acid esters, and/or the like, polyether compounds, polyester-based compounds, polyacetal compounds, and/or the like.

The additive may be included in an amount of about 0.001 parts to about 40 parts by weight based on 100 parts by weight of the resist underlayer composition. Within this range, solubility may be improved while optical properties of the resist underlayer composition are not changed.

According to some example embodiments, a resist underlayer manufactured using the aforementioned resist underlayer composition is provided. The resist underlayer may be formed by coating the aforementioned resist underlayer composition on, for example, a substrate and then curing through a heat treatment process.

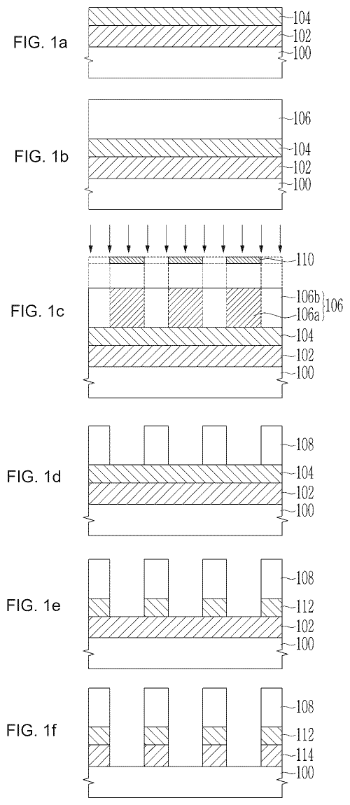

Hereinafter, a method of forming a pattern using the aforementioned resist underlayer composition is described with reference to FIGS. 1a to 1f. FIGS. 1a to 1f are cross-sectional views illustrating a method of forming a pattern using the resist underlayer composition according to embodiments of the present disclosure.

Referring to FIG. 1a, an etching target is prepared. The etching target may be a thin film 102 formed on a semiconductor substrate 100. Hereinafter, for the ease of description, the etching target is limited to the thin film 102. A surface of the thin film 102 is washed to remove impurities and/or the like remaining thereon. The thin film 102 may be, for example, a silicon nitride layer, a polysilicon layer, or a silicon oxide layer.

Subsequently, the aforementioned resist underlayer composition is coated on the surface of the cleaned thin film 102 by, e.g., applying a spin coating method.

Then, the coated composition is dried and baked to form a resist underlayer 104 on the thin film 102. The baking (e.g., heating, curing, or annealing) may be performed at about 100° C. to about 300° C., for example, about 100° C. to about 200° C. The resist underlayer composition is the same as described above in more detail and thus will not be provided.

Referring to FIG. 1b, a photoresist film 106 is formed by coating a photoresist on the resist underlayer 104.

Examples of the photoresist include a negative tone photoresist including a naphthoquinone diazide compound and a novolac resin, a chemically amplified negative tone photoresist including an acid generator capable of dissociating an acid upon exposure, a compound that decomposes in the presence of an acid to increase solubility in an organic solvent, and an organic solvent-soluble resin, a chemically amplified negative tone photoresist including an acid generator and an organic solvent-soluble resin having a group capable of imparting a resin that decomposes in the presence of an acid to increase solubility in an organic solvent, and/or the like.

Next, a first baking (e.g., heating, curing, or annealing) process is performed to heat the substrate 100 on which the photoresist film 106 is formed. The first baking (e.g., heating, curing, or annealing) process can be performed at a temperature of 90° C. to 120° C.

Referring to FIG. 1c, the photoresist film 106 may be selectively exposed. Exposure of the photoresist film 106 may be, for example, performed by positioning an exposure mask 110 having a set or predetermined pattern on a mask stage of an exposure apparatus and aligning the exposure mask 110 on the photoresist film 106. Subsequently, a set or predetermined region of the photoresist film 106 formed on the substrate 100 selectively reacts with light passing the exposure mask by radiating light into the exposure mask 110.

For example, the light used during the exposure may include short wavelength light such as an i-line having a wavelength of 365 nm, a KrF excimer laser having a wavelength of 248 nm, or an ArF excimer laser having a wavelength of 193 nm. In addition, EUV (extreme ultraviolet) having a wavelength of 13.5 nm corresponding to extreme ultraviolet light may be used.

The photoresist film 106b of the exposed region has relatively lower solubility in organic solvents compared to the photoresist film 106a of the unexposed region. Accordingly, the photoresist films of the exposed region 106b and the unexposed region 106a have different solubilities.

Next, a second baking (e.g., heating, curing, or annealing) process is performed on the substrate 100. The second baking (e.g., heating, curing, or annealing) process may be performed at a temperature of 90° C. to 150° C. By performing the second baking (e.g., heating, curing, or annealing) process, the photoresist film corresponding to the unexposed region becomes easily soluble in a suitable or specific organic solvent.

Referring to FIG. 1d, for example, by dissolving and then removing the photoresist film 106a corresponding to the unexposed region using n-butyl acetate and/or the like, the photoresist film 106b remaining after exposure forms a photoresist pattern 108.

Subsequently, the resist underlayer 104 is etched using the photoresist pattern 108 as an etch mask. An organic film pattern 112 as shown in FIG. 1e is formed through the above etching process. The etching may be, for example, dry etching using an etching gas, and the etching gas may be, for example, CHF₃, CF₄, Cl₂, O₂, or a mixed gas thereof. As described above, because the resist underlayer formed by the resist underlayer composition according to one or more embodiments has a fast etch rate, a smooth etching process may be performed within a short time.

Referring to FIG. 1f, the photoresist pattern 108 is applied as an etching mask to etch the exposed thin film 102. As a result, the thin film is formed into a thin film pattern 114. The thin film pattern 114 formed by an exposure process performed using a short wavelength light source such as an i-line (a wavelength of 365 nm), a KrF excimer laser (a wavelength of 248 nm), or an ArF excimer laser (a wavelength of 193 nm) may have a width of tens to hundreds of nm, and a thin film pattern 114 formed by the exposure process performed using the EUV light source may have a width of less than or equal to about 20 nm.

Hereinafter, the present disclosure is described in more detail through Examples regarding synthesis of the polymer and preparation of a resist underlayer composition including the same. However, the present disclosure is technically not restricted by the following examples.

### Synthesis of Polymer

### Synthesis Example 1

As a structural unit represented by Chemical Formula 1-1, a VP-8000 product of Nippon soda Co., Ltd. was purchased and used. A structural unit represented by Chemical Formula 2-2 was synthesized as follows. In a 500 mL 3-necked round flask, 15 g of poly(hydroxystyrene), 50 g of ethyl acetate, and 12 g of trimethylamine were added to 125 g of PGMEA and then, heated at 70° C. for 3 hours to proceed with a reaction, and then, the reaction solution was cooled to room temperature. After neutralization and washing by adding 7 g of acetic acid thereto, the resultant was dissolved in PGMEA.

Finally, a polymer composed of the structural unit represented by Chemical Formula 1-1 and the structural unit represented by Chemical Formula 2-2 was obtained. The structural unit represented by Chemical Formula 1-1 and the structural unit represented by Chemical Formula 2-2 have a molar ratio of 3:1, and the polymer has a weight average molecular weight (Mw) of 14,000 g/mol.

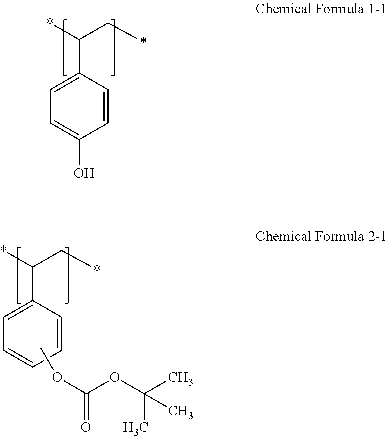

### Synthesis Example 2

A polymer was prepared similarly as Synthesis Example 1 to have the structural unit represented by Chemical Formula 1-1 and the structural unit represented by Chemical Formula 2-2 in a molar ratio of 5:1 by changing the contents of the reactants. (weight average molecular weight (Mw): 10,000 g/mol) Synthesis Example 3

A polymer was prepared similarly as Synthesis Example 1 to have the structural unit represented by Chemical Formula 1-1 and the structural unit represented by Chemical Formula 2-2 in a molar ratio of 12:1 by changing the contents of the reactants. (weight average molecular weight (Mw): 9,000 g/mol)

### Comparative Synthesis Example 1

In a 500 mL 3-necked round flask, 25.57 g of propylene glycol methyl ether acetate (PGMEA) was added, and after connecting a condenser thereto, nitrogen bubbling was performed for 10 minutes(solution 1). After preparing a reaction solution (solution 2) by mixing 32.04 g of methyl methacrylate, 22.74 g of glycidyl methacrylate, 16.58 g of dimethyl 2,2′-azobis (2-methylpropionate) (V-601;TCI), and 102.26 g of propylene glycol methyl ether acetate (PGMEA), the solution 2 was added dropwise to the solution 1, which was heated to 85° C., for 1 hour to proceed with a reaction and then, additionally stirred for 2 hours. The resulting reaction solution was cooled to room temperature and then, added dropwise to a beaker containing 600 g of heptane to produce a gum, which was dissolved in 120 g of PGMEA.

### Comparative Synthesis Example 2

A polymer composed of a structural unit represented by Chemical Formula 3 was purchased and used. (81406, Merck & Co., Inc.)

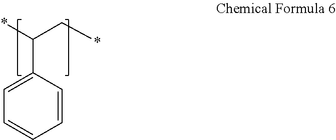

### Comparative Synthesis Example 3

A polymer composed of a structural unit represented by Chemical Formula 1-1 was purchased and used. (VP-8000, Nippon Soda Co., Ltd.)

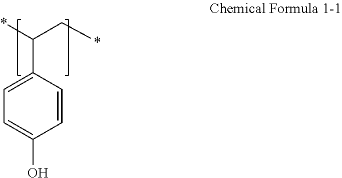

### Comparative Synthesis Example 4

A polymer was prepared in substantially the same manner as in Synthesis Example 1 except that the molar ratio of the structural unit represented by Chemical Formula 1-1 and the structural unit represented by Chemical Formula 2-2 was changed to 1:2 by changing the contents of the reactants. (weight average molecular weight (Mw): 15,000 g/mol)

### Preparation of Resist Underlayer Compositions

### Example and Comparative Example

1.2 g of each polymer according to the synthesis examples and the comparative synthesis examples, 0.4 g of a crosslinking agent (PL1174), and 0.04 g of pyridinium para-toluenesulfonic acid (PPTS) were mixed with 15 g of propylene glycol monomethylether and then, completely dissolved. The resulting solution was diluted by additionally adding a solvent, thereby preparing a resist underlayer composition according to each of the examples and the comparative examples, each including 0.5 wt % of the corresponding polymer based on a total weight of the composition.

### Evaluation: Line Width Roughness (LWR) and Pattern Collapse Evaluation

The compositions according to the examples and the comparative examples were each respectively coated using a spin-on coating method and then, heat-treated on a hot plate at 205° C. for 60 seconds to form a 50 Å-thick resist underlayer. Subsequently, on each of the resist underlayer, a photoresist solution was coated using the spin-on coating method and then, heat-treated on the hot plate at 110° C. for 1 minute to form a photoresist layer. The photoresist layer was exposed under a condition of a line with a width of 30 nm and a space with a width of 30 nm between the lines (e.g., exposed to a pattern with a 30 nm line width and a 30 nm space between the lines) by using an e-beam light exposer (acceleration voltage of 100 keV, Elionix Inc.). Subsequently, the exposed resist layer was heat-treated at 95° C. for 60 seconds and developed with n-butyl acetate for 60 seconds to form a resist pattern.

The pattern was examined with a scanning electron microscope (SEM) (S-9260, Hitachi, Ltd.) to check whether or not the pattern was collapsed, and if (e.g., when) collapsed, O was given, but if (e.g., when) not collapsed, X was given, which are shown in Table 1.

In addition, line width roughness (LWR) was measured by examining each pattern with a width of 30 nm with the scanning electron microscope (SEM) (S-9260, Hitachi, Ltd.) to measure a distance from a reference line, where the edge should be within a range (e.g., an edge range) of 2 μm along a length direction of the pattern. The results are shown in Table 1, wherein the smaller line width roughness (LWR), the better.

The LWR measurements of the examples and the comparative examples were converted into a ratio using the LWR measurement of Comparative Example 3 as a reference, and the results are shown in Table 1. The smaller line width roughness (LWR), the better pattern formality and sensitivity.

$${}^{*} LWR ( \% ) = \{ ( LWR of each Example or Comparative Example - LWR of Comparative Example 3 ) / LWR of Comparative Example 3 \} \times 100$$

TABLE 1

| | Pattern collapse occurs or not | LWR (nm) |
|---|---|---|
| Example 1 | X | −6% |
| Example 2 | X | −6% |
| Example 3 | X | −5% |
| Comparative Example 1 | ◯ | +5% |
| Comparative Example 2 | ◯ | +10% |
| Comparative Example 3 | X | Ref. |
| Comparative Example 4 | ◯ | +3% |

Referring to Table 1, the resist underlayers formed of the resist underlayer compositions of Examples 1 to 3, compared with those formed of the compositions of Comparative Examples 1 to 4, have small line width roughness and no pattern collapse and thus exhibit excellent or suitable fine pattern formality and sensitivity.

It will be understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. As used herein, the term “combination thereof” refers to a mixture, a laminate, a composite, a copolymer, an alloy, a blend, a reaction product, and/or the like of the constituents.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A device of forming patterns, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinbefore, the certain embodiments of the present disclosure have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

### REFERENCE NUMERALS

| | |
|---|---|
| 100: substrate | 102: thin film |
| 104: resist underlayer | 106: photoresist film |
| 106a: unexposed region | 106b: exposed region |
| 108: photoresist pattern | 110: mask |
| 112: organic film pattern | 114: thin film pattern |

What is claimed is:

1. A resist underlayer composition, comprising:
a polymer comprising a structural unit represented by Chemical Formula 1 and a structural unit represented by Chemical Formula 2, and
a solvent,
wherein in the polymer, a molar ratio between the structural unit represented by Chemical Formula 1 and the structural unit represented by Chemical Formula 2 is about 13:1 to about 1:1: 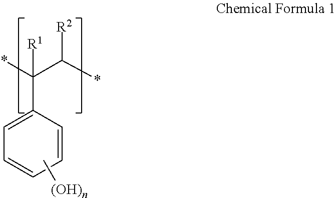
wherein, in Chemical Formula 1,
R¹ and R² are each independently hydrogen, deuterium, or a substituted or unsubstituted C1 to C5 alkyl group,
n is 1 or 2, and
* is a linking point; 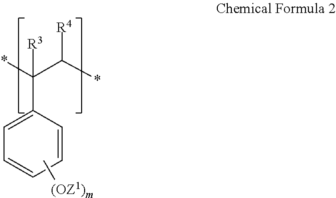
and
wherein, in Chemical Formula 2,
Z¹ is a substituted or unsubstituted C1 to C20 alkyl group; a substituted or unsubstituted C3 to C20 cycloalkyl group; a substituted or unsubstituted C1 to C20 heteroalkyl group; a substituted or unsubstituted C2 to C20 heterocycloalkyl group; —(C═O)OR^{a}, R^{a} being hydrogen, deuterium, a substituted or unsubstituted C1 to C10 alkyl group, a substituted or unsubstituted C3 to C20 cycloalkyl group, or a substituted or unsubstituted C6 to C20 aryl group; —S(═O)₂R^{b}, R^{b} is a halogen atom, a substituted or unsubstituted C1 to C20 alkyl group, a substituted or unsubstituted C1 to C20 alkoxy group, a substituted or unsubstituted C6 to C20 aryloxy group, or a substituted or unsubstituted C6 to C20 aryl group; —SiR^{c}R^{d}R^{e}, R^{c} to R^{e} being each independently a substituted or unsubstituted C1 to C10 alkyl group, or a substituted or unsubstituted C1 to C10 alkoxy group; or a combination thereof,
R³ and R⁴ are each independently hydrogen, deuterium, or a substituted or unsubstituted C1 to C5 alkyl group,
m is one of integers of 1 to 3, and
* is a linking point.

2. The resist underlayer composition as claimed in claim 1, wherein Z¹ in Chemical Formula 2 is —(C═O)OR^{a}.

3. The resist underlayer composition as claimed in claim 1, wherein m in Chemical Formula 2 is 1.

4. The resist underlayer composition as claimed in claim 1, wherein the structural unit represented by Chemical Formula 1 is represented by Chemical Formula 1-1 or Chemical Formula 1-2:

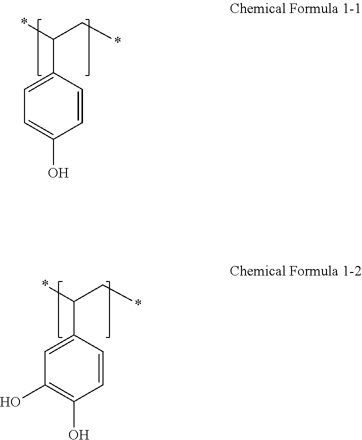

5. The resist underlayer composition as claimed in claim 1, wherein the structural unit represented by Chemical Formula 2 is represented by Chemical Formula 2-1:

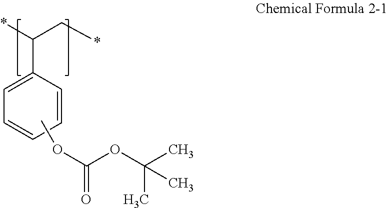

6. The resist underlayer composition as claimed in claim 1, wherein in the polymer, the molar ratio between the structural unit represented by Chemical Formula 1 and the structural unit represented by Chemical Formula 2 is about 6:1 to about 1:1.

7. The resist underlayer composition as claimed in claim 1, wherein a weight average molecular weight of the polymer is about 1,000 g/mol to about 100,000 g/mol.

8. The resist underlayer composition as claimed in claim 1, wherein the polymer is about 0.1 wt % to about 2 wt % in amount based on a total weight of the resist underlayer composition.

9. The resist underlayer composition as claimed in claim 1, wherein the composition further comprises one or more polymers selected from among an acrylic resin, an epoxy resin, a novolac-based resin, a glycoluril-based resin, and a melamine-based resin.

10. The resist underlayer composition as claimed in claim 1, wherein the composition further comprises an additive selected from among a surfactant, a thermal acid generator, a photoacid generator, a plasticizer, and a combination thereof.

11. A method comprising:
forming an etching target layer on a substrate,
forming a resist underlayer by applying the resist underlayer composition as claimed in claim 1 on the etching target layer,
forming a photoresist pattern on the resist underlayer, and
sequentially etching the resist underlayer and the etching target layer utilizing the photoresist pattern as an etching mask,
wherein the method is a method of forming patterns.

12. The method as claimed in claim 11, wherein in the polymer, the molar ratio between the structural unit represented by Chemical Formula 1 and the structural unit represented by Chemical Formula 2 is about 6:1 to about 1:1.

13. The method as claimed in claim 11, wherein the polymer is about 0.1 wt % to about 2 wt % in amount based on a total weight of the resist underlayer composition.

14. The method as claimed in claim 11, wherein the forming of the resist underlayer comprises:
coating the resist underlayer composition on the etching target layer, and
heating the substrate at about 100° C. to about 300° C.

15. The method as claimed in claim 11, wherein the etching of the resist underlayer comprises dry etching.
